(19) United States
(12) Patent Application Publication
(10) Pub. No.: US 2025/0366026 A1
(43) Pub. Date: Nov. 27, 2025

(54) SEMICONDUCTOR DEVICE

(71) Applicants: Kabushiki Kaisha Toshiba, Tokyo (JP); Toshiba Electronic Devices & Storage Corporation, Tokyo (JP)

(72) Inventors: Hirofumi KAWAI, Nonoichi Ishikawa (JP); Hiroaki KATOU, Nonoichi Ishikawa (JP); Saya FUJINO, Kanazawa Ishikawa (JP); Takuya YASUTAKE, Kanazawa Ishikawa (JP); Hyuga SAITO, Nonoichi Ishikawa (JP); Atsushi KITO, Nonoichi Ishikawa (JP); Kazuyuki SATO, Nonoichi Ishikawa (JP)

(21) Appl. No.: 19/216,141

(22) Filed: May 22, 2025

Related U.S. Application Data
(63) Continuation-in-part of application No. 18/823,650, filed on Sep. 3, 2024, now abandoned.

(30) Foreign Application Priority Data
May 24, 2024 (JP) 2024-085163
Apr. 17, 2025 (JP) 2025-068321

(51) Int. Cl. H10D 30/66; H10D 30/01; H10D 62/10; H10D 64/00; H10D 64/23; H10D 64/27; H10D 64/66

(52) U.S. Cl. CPC H10D 30/668; H10D 30/665; H10D 62/102; H10D 62/124; H10D 64/112; H10D 64/117; H10D 64/2527; H10D 64/27; H10D 64/661; H10D 30/0295; H10D 30/0297

(57) ABSTRACT

A semiconductor device according to an embodiment includes: a semiconductor portion having a cell region and a terminal region provided outside the cell region; a first electrode provided on a rear surface of the semiconductor portion; a second electrode provided on a front surface side of the semiconductor portion; a control electrode provided in the semiconductor portion via one of a plurality of first insulators arranged in a direction from the cell region to the terminal region; and a third electrode provided in the semiconductor portion via a second insulator between itself and the control electrode. A hollow portion is provided inside a terminal insulator, which is provided closer to the terminal region side than to the control electrode, among the plurality of first insulators.

### CROSS-REFERENCE TO RELATED APPLICATIONS

This application is a Continuation-in-Part of U.S. patent application Ser. No. 18/823,650, filed on Sep. 3, 2024, which is based upon and claims the benefit of priority from Japanese Patent Applications No. 2024-085163, filed on May 24, 2024 and No. 2025-068321, filed on Apr. 17, 2025; the entire contents of which are incorporated herein by reference.

### FIELD

An embodiment of the present invention relates to a semiconductor device.

### BACKGROUND

In a semiconductor device such as a MOSFET having a trench gate, there is known a structure in which a field plate at the same potential as a source electrode is disposed together with the gate electrode inside a gate trench.

In the semiconductor device as described above, a gate trench is formed in a terminal region as well. At a final end of the terminal region, a terminal trench is further formed. Since the internal structure is different between the gate trench and the terminal trench, stress may occur. This stress may cause destruction of the semiconductor device. That is, there is concern about deterioration of the reliability of the semiconductor device.

### BRIEF DESCRIPTION OF THE DRAWINGS

FIG. 1 is a cross-sectional view of a semiconductor device according to a first embodiment;

FIG. 2 is a cross-sectional view illustrating a process of forming an insulator on the inner surface of each of a trench and a terminal trench;

FIG. 3 is a cross-sectional view illustrating a process of forming a third electrode and a fourth electrode;

FIG. 4 is a cross-sectional view illustrating a process of etching a third electrode and a part of the fourth electrode;

FIG. 5 is a cross-sectional view illustrating a process of covering the upper surfaces of the third electrode and the fourth electrode with an insulator;

FIG. 6 is a cross-sectional view illustrating a process of filling the inside of the trench with an insulator;

FIG. 7 is a cross-sectional view illustrating a process of removing an upper part of the insulator;

FIG. 8 is a cross-sectional view illustrating a process of forming a gate insulator;

FIG. 9 is a cross-sectional view illustrating a process of forming a control electrode;

FIG. 10 is a cross-sectional view illustrating a process of forming a second semiconductor layer and a third semiconductor layer;

FIG. 11 is a cross-sectional view illustrating a process of dividing the control electrode into a first controller and a second controller;

FIG. 12 is a cross-sectional view illustrating a process of forming an insulator in a trench;

FIG. 13 is a cross-sectional view illustrating a process of etching an insulator formed directly above the fourth electrode;

FIG. 14 is a cross-sectional view illustrating a process of etching the fourth electrode;

FIG. 15 is a cross-sectional view illustrating a process of forming a hollow portion 61 in a terminal trench;

FIG. 16 is a cross-sectional view illustrating a process of forming a fourth semiconductor layer in the second semiconductor layer;

FIG. 17 is a cross-sectional view of a semiconductor device according to a comparative example;

FIG. 18 is a cross-sectional view of a semiconductor device according to a first variation;

FIG. 19 is a cross-sectional view of a semiconductor device according to a second embodiment;

FIG. 20 is a cross-sectional view illustrating a process of etching a part of the fourth electrode;

FIG. 21 is a cross-sectional view illustrating a process of forming an insulator in a terminal trench;

FIG. 22 is a cross-sectional view of a semiconductor device according to a second variation;

FIG. 23 is a cross-sectional view of a semiconductor device according to a third embodiment;

FIG. 24 is a cross-sectional view illustrating a process of implanting ions into the third electrode with resist placed on the fourth electrode; and

FIG. 25 is a cross-sectional view of a semiconductor device according to a third variation;

FIG. 26 is a cross-sectional view of a semiconductor device according to a fourth embodiment;

FIG. 27 is a cross-sectional view illustrating a process of forming an insulator on the inner surface of each of a trench and a terminal trench;

FIG. 28 is a cross-sectional view illustrating a process of forming a third electrode and a fourth electrode;

FIG. 29 is a cross-sectional view illustrating a process of etching a part of a third electrode and the fourth electrode;

FIG. 30 is a cross-sectional view illustrating an oxidation process;

FIG. 31 is a cross-sectional view of a semiconductor device according to a fourth variation;

FIG. 32 is a cross-sectional view of a semiconductor device according to a fifth embodiment; and

FIG. 33 is a cross-sectional view of a semiconductor device according to a fifth variation.

### DETAILED DESCRIPTION

Embodiments will now be explained with reference to the accompanying drawings. The present invention is not limited to the embodiments.

A semiconductor device according to an embodiment includes:
a semiconductor portion having a cell region and a terminal region provided outside the cell region;
a first electrode provided on a rear surface of the semiconductor portion;
a second electrode provided on a front surface side of the semiconductor portion;
a control electrode provided in the semiconductor portion via one of a plurality of first insulators arranged in a direction from the cell region to the terminal region; and
a third electrode provided in the semiconductor portion via a second insulator between itself and the control electrode.

There is provided a hollow portion inside a terminal insulator, which is provided closer to the terminal region than to the control electrode, among the plurality of first insulators.

### First Embodiment

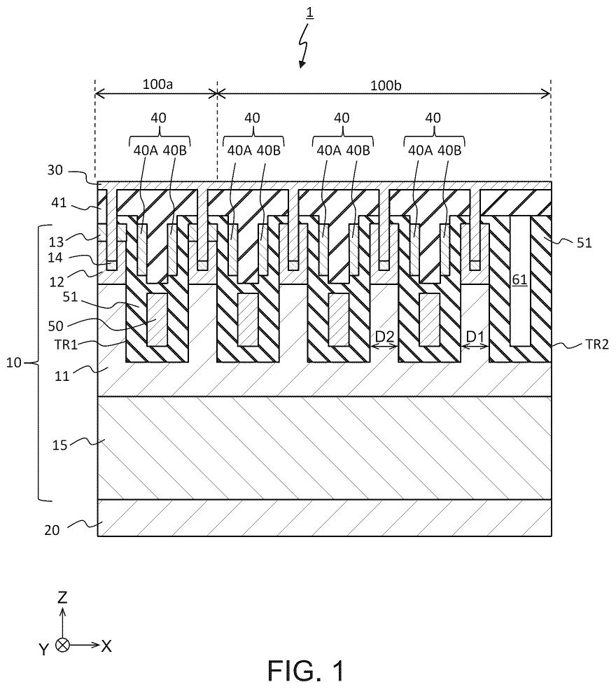

FIG. 1 is a cross-sectional view of a semiconductor device according to a first embodiment. In the following description, the arrangement and configuration of each part of the semiconductor device may be described using an X-axis, a Y-axis, and a Z-axis shown in each figure. The X-axis, the Y-axis, and the Z-axis are orthogonal to each other and represent X, Y, and Z directions, respectively. In addition, the Z direction may be described as an upward direction and the opposite direction thereof may be described as a downward direction. In the present embodiment, the X direction and the Y direction correspond to a first direction and a third direction and represent in-plane directions parallel to the front surface (or rear surface) of the semiconductor device 1. The Z direction corresponds to a second direction and represents an out-of-plane direction orthogonal to the front surface (or rear surface) of the semiconductor device 1.

Further, the notation of “p” and “p⁺” means that p-type impurity concentration increases in this order. Furthermore, the notation of “n⁻”, “n”, and “n⁺” means that the n-type impurity concentration increases in this order.

The impurity concentration can be measured, for example, by SIMS (Secondary Ion Mass Spectrometry). Further, the relative magnitude of impurity concentration can be determined, for example, from the magnitude of carrier concentration obtained by SCM (scanning capacitance microscopy). Further, a distance such as a depth of a semiconductor region can be obtained by SIMS, for example.

A semiconductor device 1 shown in FIG. 1 is, for example, a MOSFET. The semiconductor device 1 includes a semiconductor portion 10, a first electrode 20, a second electrode 30, a control electrode 40, and a third electrode 50.

The material of the semiconductor portion 10 is, for example, silicon. The semiconductor portion 10 includes, for example, a rear surface on which the first electrode 20 is provided, and a front surface opposite thereto. The second electrode 30 is provided on the front surface side of the semiconductor portion 10. The first electrode 20 is a drain electrode.

The first electrode 20 is provided on the rear surface of the semiconductor portion 10. The second electrode 30 is a source electrode. The semiconductor portion 10 includes a cell region 100a and a terminal region 100b.

The cell region 100a switches between an on-state and an off-state according to the voltage applied to the control electrode 40. In the on state, a current path is formed through which current flows from the first electrode 20 to the second electrode 30. In the off state, since the current path is not formed, current does not flow from the first electrode 20 to the second electrode 30.

The terminal region 100b is provided outside the cell region 100a. In the terminal region 100b, the above described current path is not formed regardless of whether or not voltage is applied to the control electrode 40 so that current does not flow from the first electrode 20 to the second electrode 30.

The semiconductor portion 10 includes a first semiconductor layer 11 of a first conductivity type, a second semiconductor layer 12 of a second conductivity type, a third semiconductor layer 13 of a first conductivity type, a fourth semiconductor layer 14 of a second conductivity type, and a fifth semiconductor layer 15 of a first conductivity type. In the present embodiment, the first conductive type is an n-type and the second conductive type is a p-type.

The first semiconductor layer 11 is an n-type drift layer. The first semiconductor layer 11 is provided between the first electrode 20 and the second electrode 30.

The second semiconductor layer 12 is a p-type diffusion layer. The second semiconductor layer 12 is provided on the first semiconductor layer 11.

The third semiconductor layer 13 is an n⁺-type source layer. The third semiconductor layer 13 is provided on the second semiconductor layer 12. The third semiconductor layer 13 contains a first conductivity type impurity at a concentration higher than the first conductivity-type impurity concentration of the first semiconductor layer 11 and is electrically connected to the second electrode 30. The third semiconductor layer 13 is provided in the cell region 100a but is not provided in the terminal region 100b.

The fourth semiconductor layer 14 is a p⁺-type contact layer. The fourth semiconductor layer 14 is connected to the second electrode 30 in the second semiconductor layer 12. The fourth semiconductor layer 14 contains a second conductivity type impurity in a higher concentration than the second conductivity impurity concentration of the second semiconductor layer 12 and is electrically connected to the second electrode 30. In the present embodiment, the fourth semiconductor layer 14 is provided in the second semiconductor layer 12. The second semiconductor layer 12 is electrically connected to the second electrode 30 via the fourth semiconductor layer 14.

The fifth semiconductor layer 15 is an n-type drain layer. The fifth semiconductor layer 15 is provided between the first semiconductor layer 11 and the first electrode 20. The fifth semiconductor layer 15 contains a first conductivity-type impurity at a concentration higher than the first conductive impurity concentration of the first semiconductor layer 11 and is electrically connected to the first electrode 20.

The control electrode 40 provided in the cell region 100a is a gate electrode. The control electrode 40 is located between the first electrode 20 and the second electrode 30 and is provided inside the trench TR1 opened at the front surface of the semiconductor portion 10. On the other hand, in the terminal region 100b, as described above, the third semiconductor layer 13 is not provided in the terminal region 100b. Therefore, the control electrode 40 provided in the terminal region 100b is a dummy gate electrode.

The third electrode 50 is a field plate. The third electrode 50 is electrically connected to the second electrode 30 and is provided inside the trench TR1 away from the control electrode 40. The third electrode 50 is provided to be located in the first semiconductor layer 11. In the trench TR1, the distance from the third electrode 50 to the first electrode 20 is shorter than the distance from the control electrode 40 to the first electrode 20.

As shown in FIG. 1, the control electrode 40 is provided at the same level as the second semiconductor layer 12 in the direction from the first electrode 20 to the second electrode 30, that is, in the Z direction. The control electrode 40 includes a first controller 40A and a second controller 40B. The first controller 40A and the second controller 40B are lined up in the X direction inside the trench TR1.

The trench TR1 extends in the X direction from the second electrode 30 to the first electrode 20 and has a depth from the front surface side of the semiconductor portion 10 up to the inside of the first semiconductor layer 11.

The terminal trench TR2 is provided at the outermost final end of the terminal region 100b. The terminal trench TR2 has a depth equivalent to that of the trench TR1. A hollow portion 61 surrounded by an insulator 41 and an insulator 51 is provided in the terminal trench TR2. In the present embodiment, the position of the lower end of the hollow portion 61 is the same as that of the lower end of the third electrode 50.

In the present embodiment, it is preferable that an interval D1 between the trench TR1 adjacent to the terminal trench TR2 and the terminal trench TR2 is smaller than an interval D2 between the trenches TR1. This is because it is possible to secure a sufficient breakdown voltage in the terminal region 100b. Note that the hollow portion 61 may be continuously formed so as to surround the entire circumference of the cell region 100a or may be formed intermittently so as to partially surround the circumference of the cell region 100a.

In the present embodiment, a plurality of trenches TR1 are provided side by side in the X direction in each of the cell region 100a and the terminal region 100b. The second semiconductor layer 12 is provided between the plurality of trenches TR1, respectively, and is opposed to the first controller 40A and the second controller 40B of the control electrode 40 via the insulator 51.

As shown in FIG. 1, the semiconductor device 1 further includes an insulator 41 and an insulator 51. In the present embodiment, the insulator 41 corresponds to the second insulator, and the insulator 51 corresponds to the first insulator.

The insulator 41 is provided so as to cover the first controller 40A and the second controller 40B in the trench TR1. Further, the insulator 41 is provided between the second electrode 30 and the control electrode 40 and functions as an interlayer insulator that electrically insulates the control electrode 40 from the second electrode 30. Further, the insulator 41 is provided between the semiconductor portion 10 and the third electrode 50 and electrically insulates the third electrode 50 from the semiconductor portion 10.

The insulator 51 is provided between the semiconductor portion 10 and the control electrode 40 and functions as a gate insulator that electrically insulates the control electrode 40 from the semiconductor portion 10. The second semiconductor layer 12 is provided so as to be opposed to the control electrode 40 via the gate insulator. The third semiconductor layer 13 comes into contact with the gate insulator between the second semiconductor layer 12 and the second electrode 30. Further, the insulator 51 is provided between the insulator 41 and the third electrode 50. Further, the insulator 51 is formed on an inner surface of the terminal trench TR2 so as to surround the hollow portion 61. The insulator 51 formed on the inner surface of the terminal trench TR2 is also referred to as a terminal insulator. Further, the insulator 51 formed on the inner surface of the trench TR1 adjacent to the terminal trench TR2 is also referred to as an adjacent insulator.

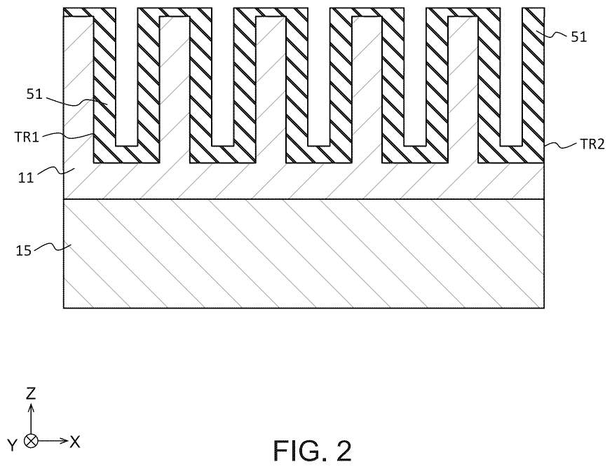

Hereinafter, with reference to FIGS. 2 to 16, a manufacturing method of the semiconductor device 1 according to the present embodiment will be described. Here, the process after forming the trench TR1 and the terminal trench TR2 will be described.

First, as shown in FIG. 2, an insulator 51 is formed on the inner surface of each of the trench TR1 and the terminal trench TR2. The insulator 51 is formed using, for example, silicon oxide (SiO₂).

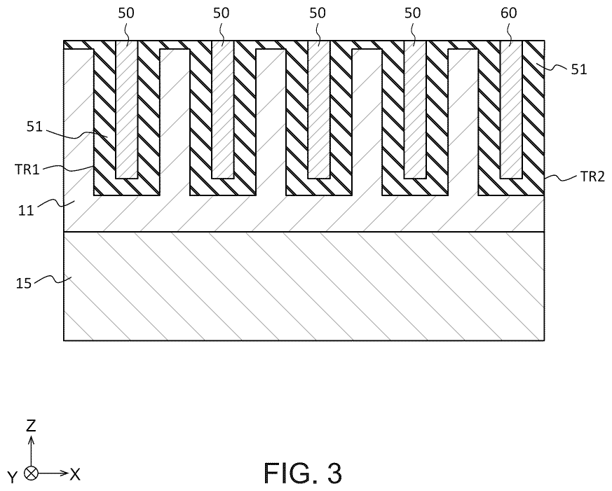

Next, as shown in FIG. 3, a third electrode 50 is formed in the trench TR1 and a fourth electrode 60 is formed in the terminal trench TR2. The third electrode 50 and the fourth electrode 60 are formed, for example, using polysilicon. The materials of the third electrode 50 and the fourth electrode 60 may be of the same material without being limited to polysilicon.

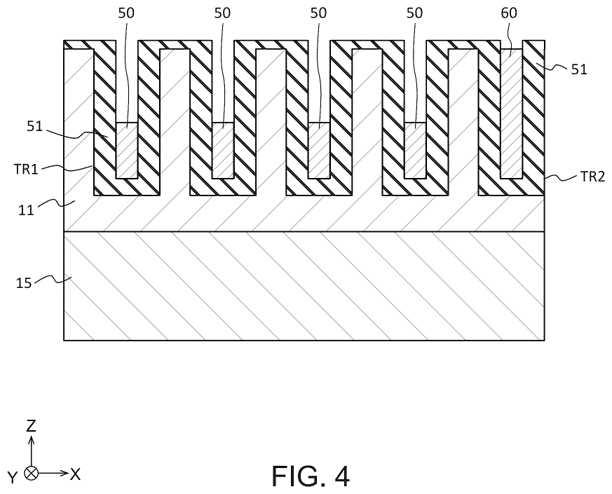

Next, as shown in FIG. 4, parts of the third electrode 50 and the fourth electrode 60 are etched, for example, by CDE (chemical dry etching). At this time, the thickness of the mask etc. are adjusted such that the etching amount of the fourth electrode 60 is less than the etching amount of the third electrode 50.

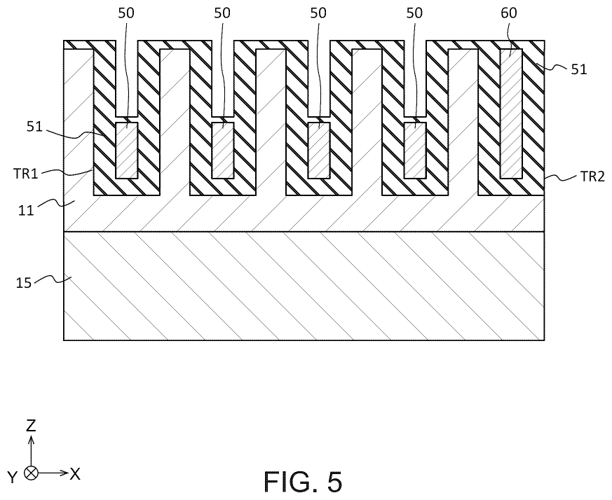

Next, as shown in FIG. 5, upper surfaces (exposed surfaces) of the third electrode 50 and the fourth electrode 60 are covered with an insulator 51. At this time, the upper end of the trench TR1 is open, while the upper end of the terminal trench TR2 is blocked with the insulator 51.

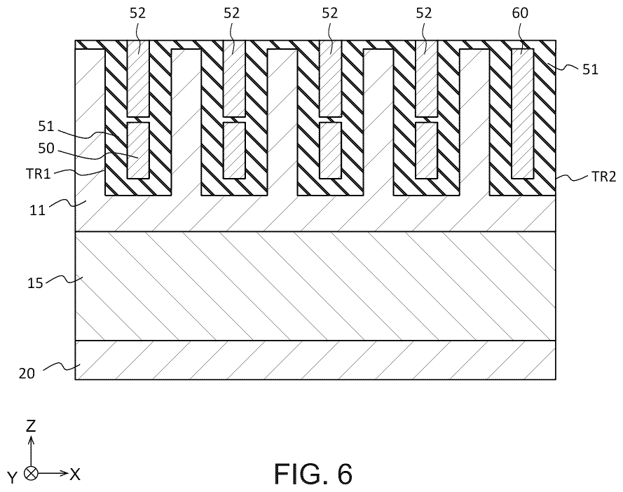

Next, as shown in FIG. 6, the inside of the trench TR1 is filled with the insulator 52. The insulator 52 corresponds to a third insulator and is formed using, for example, BPSG (boron phosphorus silicon glass).

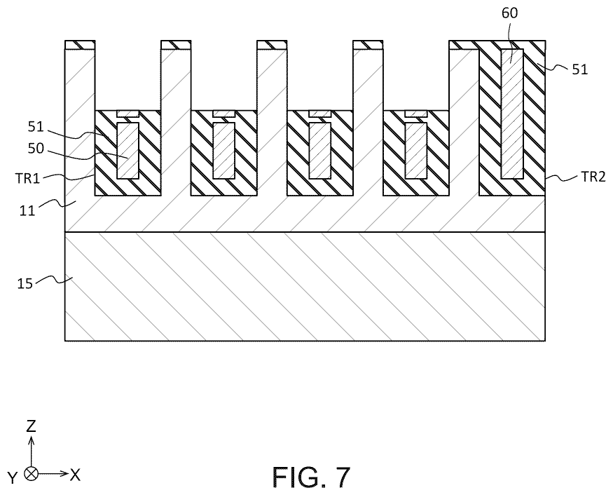

Next, as shown in FIG. 7, a portion located above the third electrode 50 in the insulator 51 formed in the trench TR1 and an insulator 52 surrounded by that portion are etched.

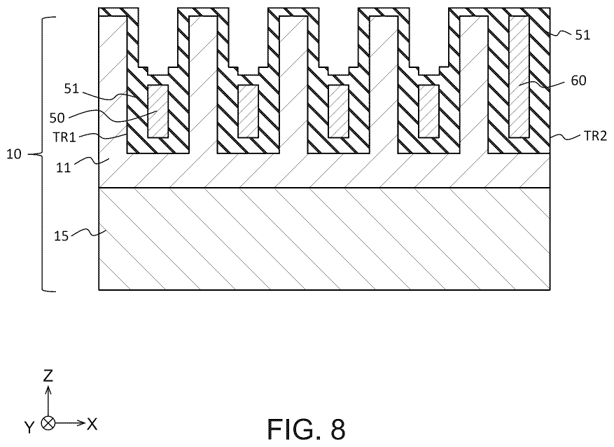

Next, as shown in FIG. 8, the insulator 52 is removed, and subsequently an insulator 51 that functions as a gate insulator is formed in the trench TR1.

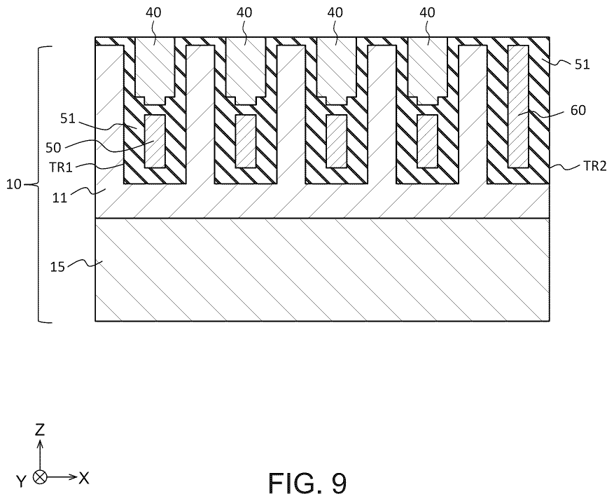

Next, as shown in FIG. 9, a control electrode 40 is formed in the trench TR1. The control electrode 40 can be formed, for example, by filling polysilicon into the trench TR1.

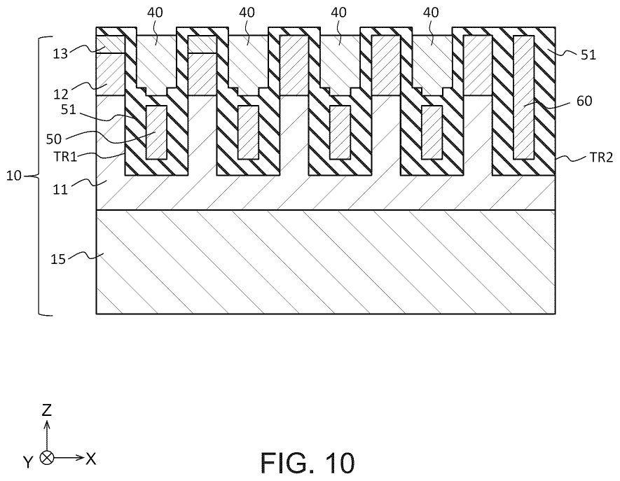

Next, as shown in FIG. 10, the upper part of the control electrode 40 is etched. The control electrode 40 is removed, for example, by CDE. Subsequently, a second semiconductor layer 12 is formed on top of the first semiconductor layer 11. The second semiconductor layer 12 can be formed, for example, by implanting and diffusing p-type impurities. Subsequently, a third semiconductor layer 13 is formed on top of the second semiconductor layer 12. The third semiconductor layer 13 can be formed, for example, by implanting and diffusing n-type impurities. However, while the third semiconductor layer 13 is formed in the cell region 100a, it is not formed in the terminal region 100b.

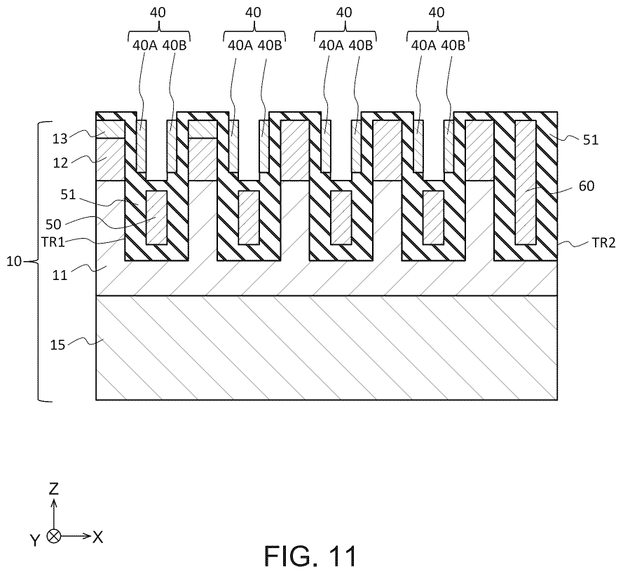

Next, as shown in FIG. 11, a central portion of the control electrode 40 is removed. As a result, the control electrode 40 is divided into a first controller 40A and a second controller 40B.

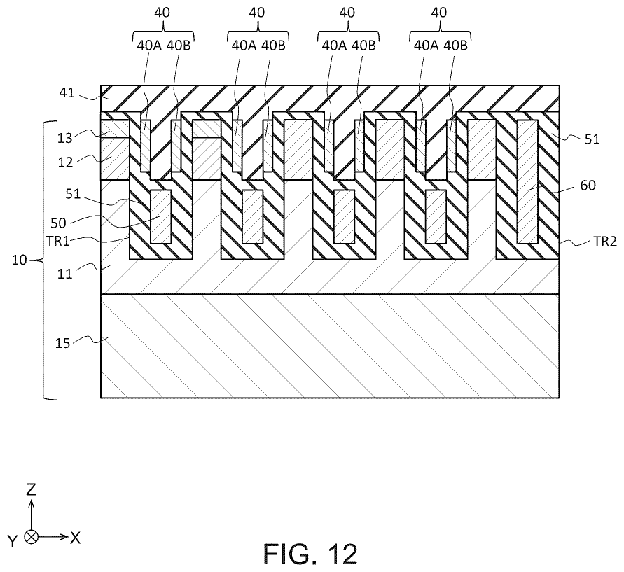

Next, as shown in FIG. 12, an insulator 41 is formed in the trench TR1. The insulator 41 can be formed by CVD (chemical vapor deposition) using, for example, a non-doped BPSG.

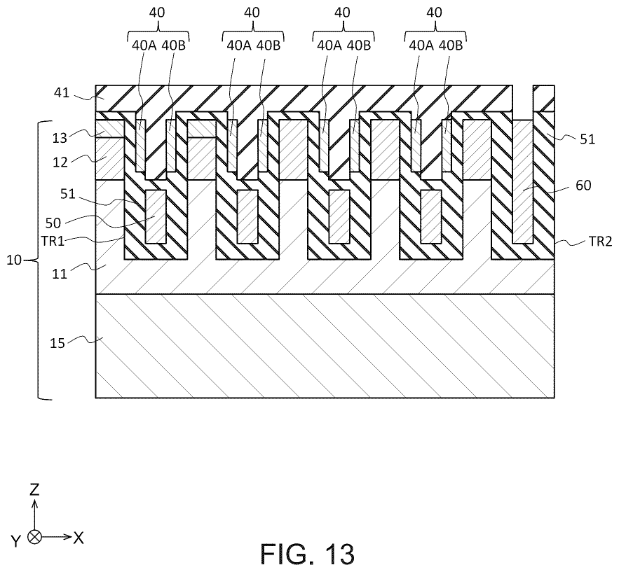

Next, as shown in FIG. 13, the insulator 41 and the insulator 51 formed directly above the fourth electrode 60 are etched. The insulator 41 and the insulator 51 can be removed, for example, by CDE or RIE (reactive ion etching).

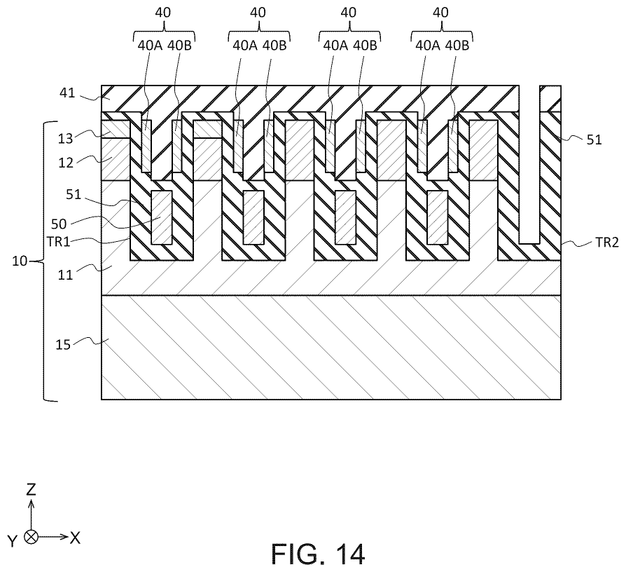

Next, as shown in FIG. 14, the fourth electrode 60 is etched. As a result, a cavity with an opening at an upper end is formed in the terminal trench TR2.

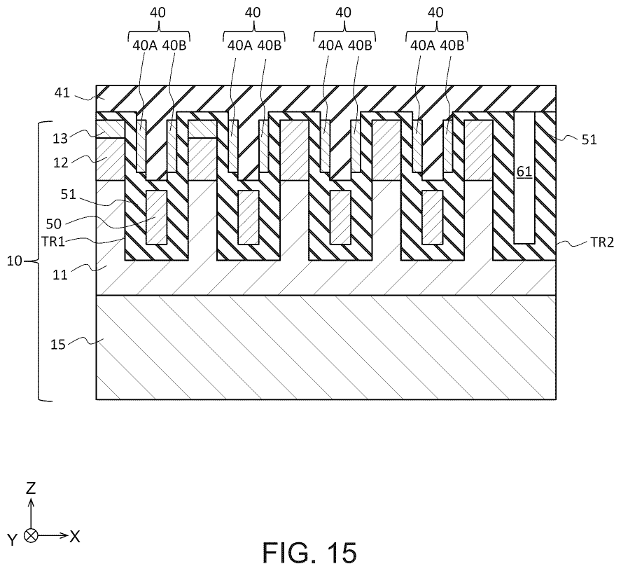

Next, as shown in FIG. 15, the insulator 41 is formed so as to block the upper end opening of the terminal trench TR2. Thereby, a hollow portion 61 is formed in the terminal trench TR2. The insulator 41 can be deposited by, for example, CVD.

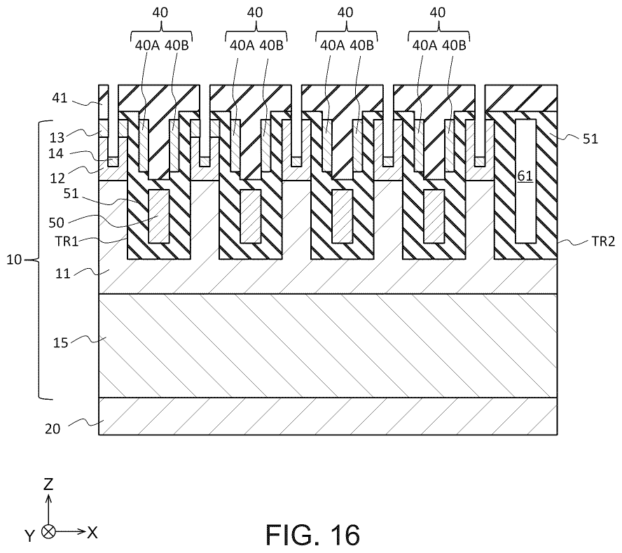

Next, as shown in FIG. 16, a fourth semiconductor layer 14 is formed in the second semiconductor layer 12. The fourth semiconductor layer 14 can be formed, for example, by forming a trench TR3 which penetrates the insulator 41 and the third semiconductor layer 13 in the Z direction and is terminated at the second semiconductor layer 12, and subsequently implanting and diffusing p-type impurities from the trench TR3.

Finally, returning to FIG. 1, the first electrode 20 and the second electrode 30 are formed. As a result, the semiconductor device 1 shown in FIG. 1 is completed.

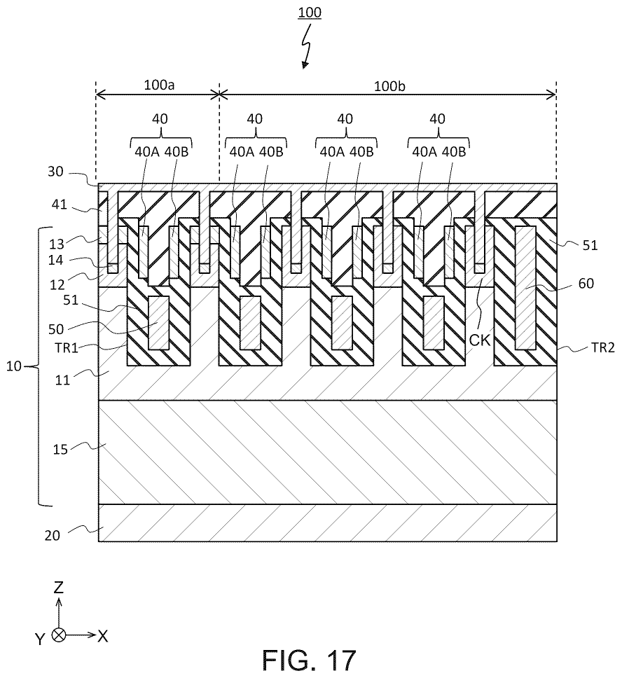

Here, a comparative example to be compared with the present embodiment will be described. FIG. 17 is a cross-sectional view of a semiconductor device according to a comparative example. In FIG. 17, the same components as those of the semiconductor device 1 described above are denoted by the same reference numerals, thereby omitting duplicate descriptions thereof.

In the semiconductor device 100 shown in FIG. 17, the fourth electrode 60 remains in the terminal trench TR2. Between the fourth electrode 60 and the third electrode 50, the position of each lower end portion is substantially the same. However, the fourth electrode 60 terminates at the upper end of the terminal trench TR2, while the upper-end part of the third electrode 50 terminates in the middle of the trench TR1.

As described above, if the internal structure is different between the trench TR1 and the terminal trench TR2, due to the expansion stress of the fourth electrode 60, a crack CK (see FIG. 17) may occur in a mesa area between the terminal trench TR2 and the trench TR1. In this case, since a leakage current occurs, long-term reliability may become insufficient.

On the other hand, in the present embodiment, as shown in FIG. 14, the fourth electrode 60 formed in the terminal trench TR2 is removed. As a result, since the inside of the terminal trench TR2 becomes hollow, the expansion stress of the fourth electrode 60 will not occur. Therefore, according to the present embodiment, it becomes possible to improve reliability.

### (First Variation)

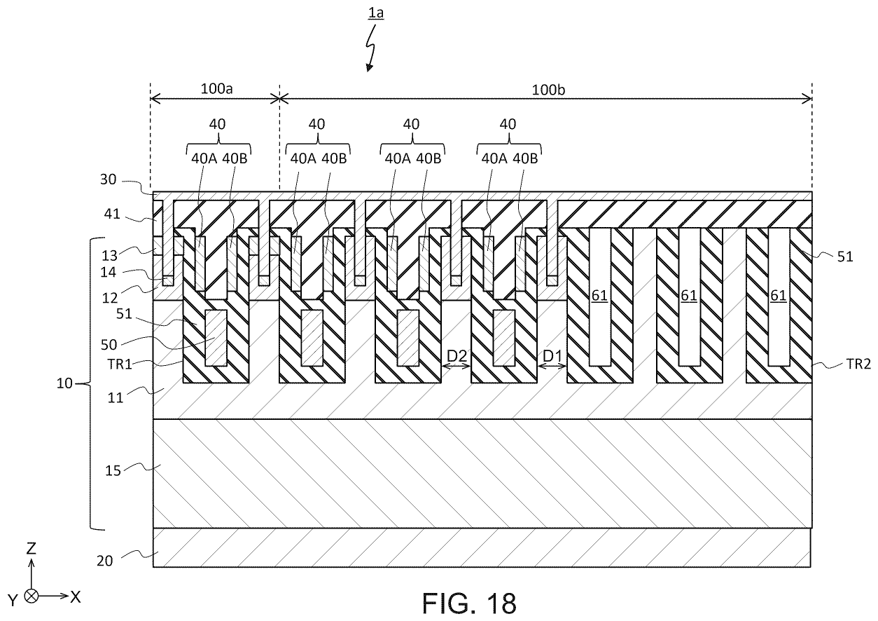

FIG. 18 is a cross-sectional view of a semiconductor device according to a first variation. In FIG. 18, differences from the semiconductor device 1 according to the first embodiment described above will be mainly described. The same components as those of the semiconductor device 1 according to the first embodiment are denoted by the same reference numerals, thereby omitting duplicate descriptions thereof.

In a semiconductor device 1a according to the present variation, a plurality of terminal trenches TR2 are lined up in the X direction. That is, the cell region 100a is surrounded by a plurality of terminal trenches TR2 in multiple layers.

Each terminal trench TR2 has a hollow portion 61 described in the first embodiment. Therefore, even if a plurality of terminal trenches TR2 are provided as in the present variation, the expansion stress of the fourth electrode 60 will not occur. Therefore, in the present variation as well, it becomes possible to improve reliability.

### Second Embodiment

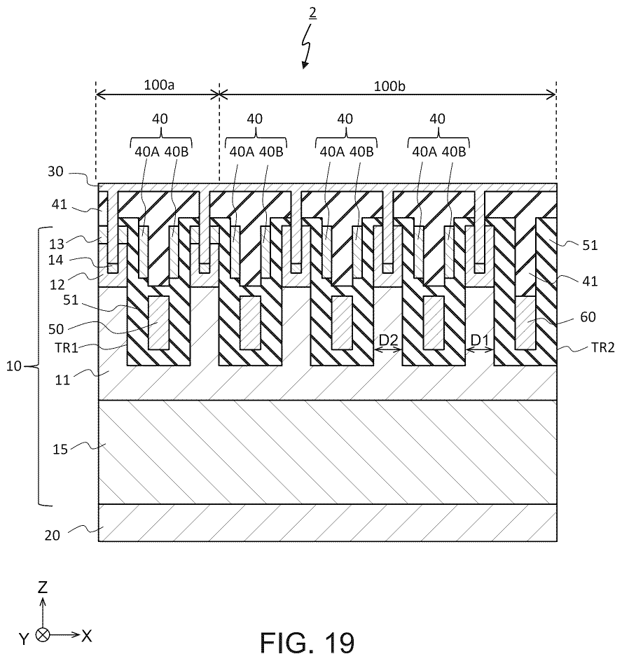

FIG. 19 is a cross-sectional view of a semiconductor device according to a second embodiment. In FIG. 19, differences from the semiconductor device 1 according to the first embodiment described above will be mainly described. The same components as those of the semiconductor device 1 according to the first embodiment are denoted by the same reference numerals, thereby omitting duplicate descriptions thereof.

In a semiconductor device 2 according to the present embodiment, the internal structure of the terminal region 100b is different from that of the first embodiment. In the semiconductor device 1 according to the first embodiment described above, the inside of the terminal region 100b is hollow as shown in FIG. 1.

On the other hand, in the terminal region 100b of the semiconductor device 2 according to the present embodiment, as shown in FIG. 19, a fourth electrode 60 is provided in a lower part of the internal space surrounded by the insulator 51. Further, an insulator 41 is provided in the upper part of this internal space, that is, on the fourth electrode 60.

In order to make the internal structure the same between the trench TR1 and the terminal trench TR2, each position of the upper end part and lower end part of the fourth electrode 60 from the upper end of the terminal trench TR2 is preferably equal to each position of the upper end part and lower end part of the third electrode 50 from the upper end of the trench TR1. In other words, it is preferable that the thickness (length in the Z direction) of the fourth electrode 60 is equal to the thickness (length in the Z direction) of the third electrode 50.

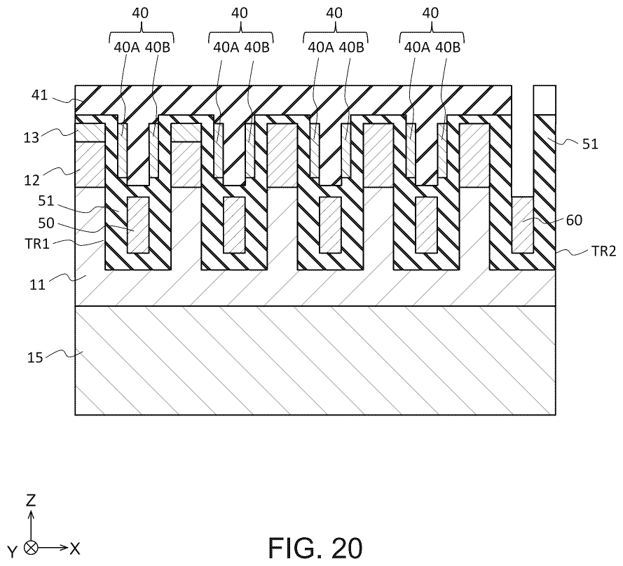

Hereinafter, with reference to FIGS. 20 to 22, a manufacturing method of the semiconductor device 2 according to the present embodiment will be described. Here, differences from the first embodiment will be mainly described.

In the present embodiment, processes from forming the trench TR1 and the terminal trench TR2 (see FIG. 2) to forming the insulator 41 in the trench TR1 (see FIG. 12) are the same as those in the first embodiment. Therefore, description thereof will be omitted.

Next, in the present embodiment, as shown in FIG. 20, the insulator 41 and the insulator 51 formed on the terminal trench TR2 are etched as well as a part of the fourth electrode 60 is etched. At this time, the thickness of the fourth electrode 60 that remains after etching becomes substantially equal to the thickness of the third electrode 50.

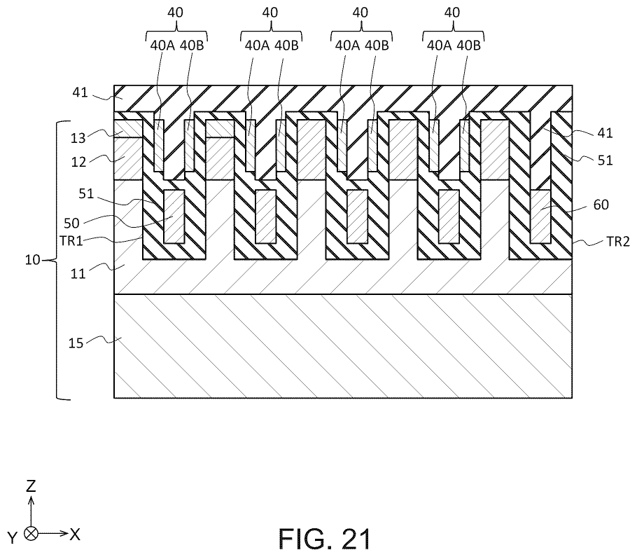

Next, as shown in FIG. 21, an insulator 41 is formed in the terminal trench TR2. The insulator 41 can be formed by CVD (chemical vapor deposition) using, for example, a non-doped BPSG.

Finally, returning to FIG. 19, a fourth semiconductor layer 14 is formed in the second semiconductor layer 12 in the same manner as in the first embodiment, and then the first electrode 20 and the second electrode 30 are formed. As a result, the semiconductor device 2 shown in FIG. 19 is completed.

In the present embodiment described above, although a fourth electrode 60 is provided in the terminal trench TR2, the thickness of the fourth electrode 60 is substantially the same as that of the third electrode 50 formed in the trench TR1. Further, while the insulator 41 is provided on the fourth electrode 60 in the terminal trench TR2, the insulator 41 is provided on the third electrode 50 in the trench TR1.

As described above, the internal structure is similar between the terminal trench TR2 and the trench TR1. As a result, the expansion stress of the fourth electrode 60 is mitigated. Therefore, in the present embodiment as well, it becomes possible to improve reliability.

### (Second Variation)

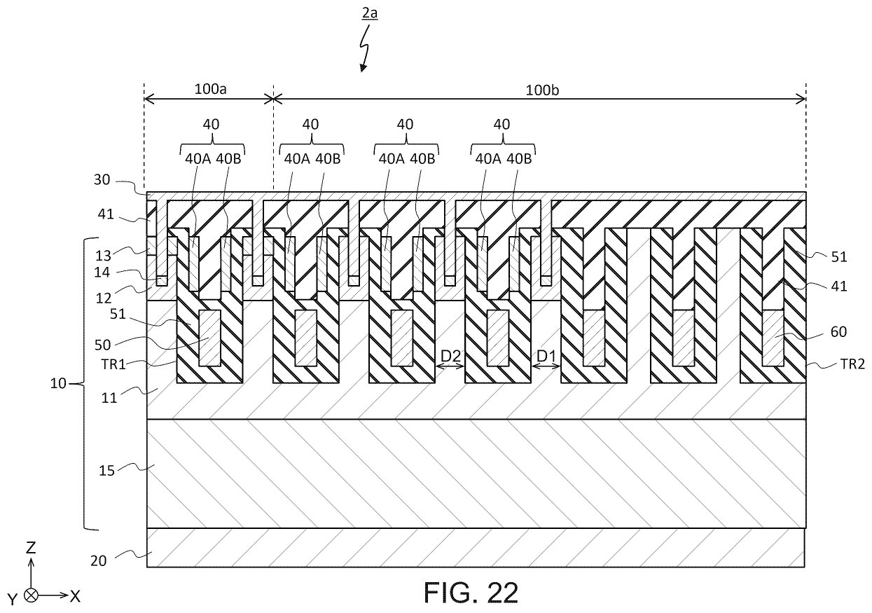

FIG. 22 is a cross-sectional view of a semiconductor device according to a second variation. FIG. 22 will mainly describe differences from the semiconductor device 2 according to the second embodiment described above. The same components as those of the semiconductor device 2 according to the second embodiment are denoted by the same reference numerals, thereby omitting duplicate descriptions thereof.

In a semiconductor device 2a according to the present variation, a plurality of terminal trenches TR2 are lined up in the X direction. That is, the cell region 100a is surrounded by the plurality of terminal trenches TR2 in multiple layers.

Each terminal trench TR2 has a fourth electrode 60 and an insulator 41 as in the second embodiment. The shape, dimensions, and arrangement of the fourth electrode 60 in the terminal trench TR2 are substantially the same as those of the third electrode 50 in the trench TR1. Further, an insulator 41 is formed on the fourth electrode 60 in the terminal trench TR2, and the insulator 41 is formed on the third electrode 50 in the trench TR1. Therefore, even if a plurality of terminal trenches TR2 are provided as in the present variation, the expansion stress of the fourth electrode 60 is mitigated. Therefore, in the present variation as well, it becomes possible to improve reliability.

### Third Embodiment

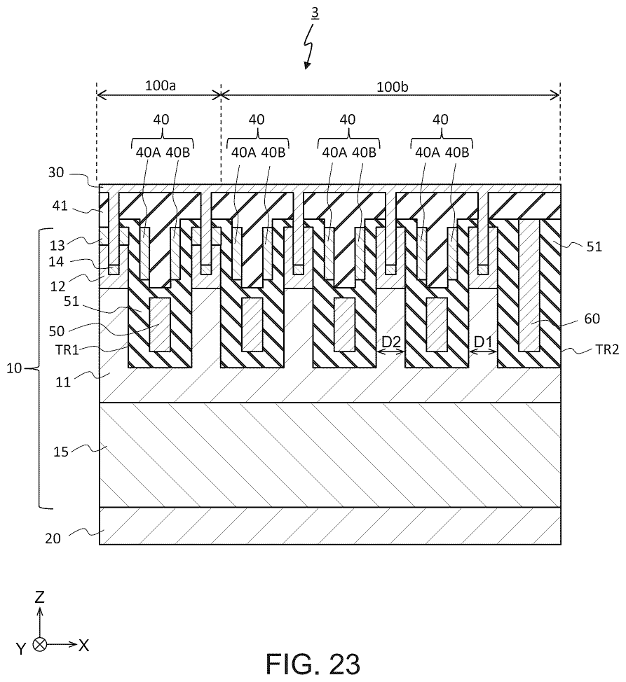

FIG. 23 is a cross-sectional view of a semiconductor device according to a third embodiment. In FIG. 23, differences from the semiconductor device 2 according to the second embodiment described above will be mainly described. The same components as those of the semiconductor device 2 according to the second embodiment are denoted by the same reference numerals, thereby omitting duplicate descriptions thereof.

In a semiconductor device 3 according to the present embodiment, the internal structure of the terminal trench TR2 is different from that of the second embodiment. In the semiconductor device 2 according to the second embodiment described above, as shown in FIG. 19, the fourth electrode 60 and the insulator 41 covering the fourth electrode 60 are formed in the internal space surrounded by the insulator 51 in the terminal trench TR2.

On the other hand, in the terminal trench TR2 of the semiconductor device 3 according to the present embodiment, as shown in FIG. 23, the internal space surrounded by the insulator 51 is filled with the fourth electrode 60, and the insulator 41 is not formed.

In the second embodiment, the fourth electrode 60 and the third electrode 50 are made of polysilicon containing impurities, and the concentration of the impurities is the same between the fourth electrode 60 and the third electrode 50. On the other hand, in the present embodiment, the concentration of the impurities contained in the fourth electrode 60 is lower than the concentration of the impurities contained in the third electrode 50. For example, the fourth electrode 60 may be made of a non-doped polysilicon that does not contain impurities.

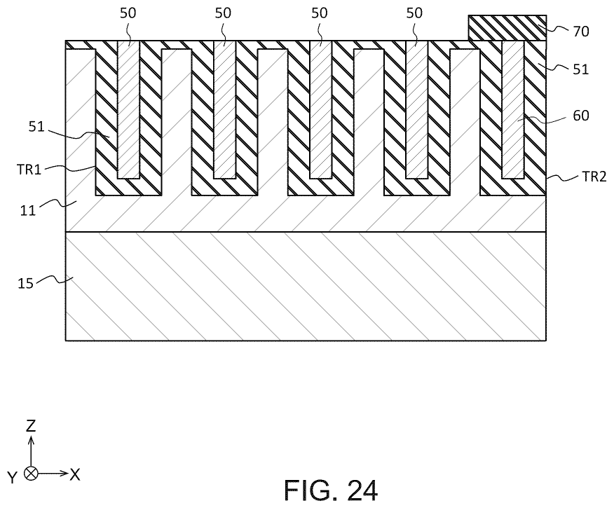

Hereinafter, with reference to FIG. 24, a manufacturing method of the semiconductor device 3 according to the present embodiment will be described. Here, differences from the second embodiment will be mainly described.

In the present embodiment, in the process of forming a third electrode 50 in the trench TR1 and forming a fourth electrode 60 in the terminal trench TR2 (see FIG. 3), a non-doped polysilicon is used for the materials of the third electrode 50 and the fourth electrode 60.

Next, as shown in FIG. 24, resist 70 is disposed on the fourth electrode 60. Subsequently, phosphorus (P) as an impurity, for example, is ion-implanted from above the third electrode 50. At this time, since the resist 70 functions as a mask, the implantation of phosphorus into the fourth electrode 60 is blocked. Subsequently, annealing is performed. Thereby, the impurity (phosphorus) is diffused in the third electrode 50.

Since the subsequent processes are the same as those of the second embodiment, description thereof will be omitted. However, in the present embodiment, the process of etching a part of the fourth electrode 60 (see FIG. 20) is not performed.

In the semiconductor device 3 according to the present embodiment described above, a fourth electrode 60 is provided in the terminal trench TR2. If the concentration of the impurity (phosphorus) contained in the fourth electrode 60 is high, enhanced oxidation of the fourth electrode 60 is promoted. As a result, the expansion stress of the fourth electrode 60 will increase.

However, in the present embodiment, the concentration of the impurity contained in the fourth electrode 60 is made lower than the concentration of the impurity contained in the third electrode 50. Therefore, since enhanced oxidation of the fourth electrode 60 is suppressed compared to the third electrode 50, the expansion stress of the fourth electrode 60 is mitigated. Therefore, in the present embodiment as well, it becomes possible to improve reliability.

### (Third Variation)

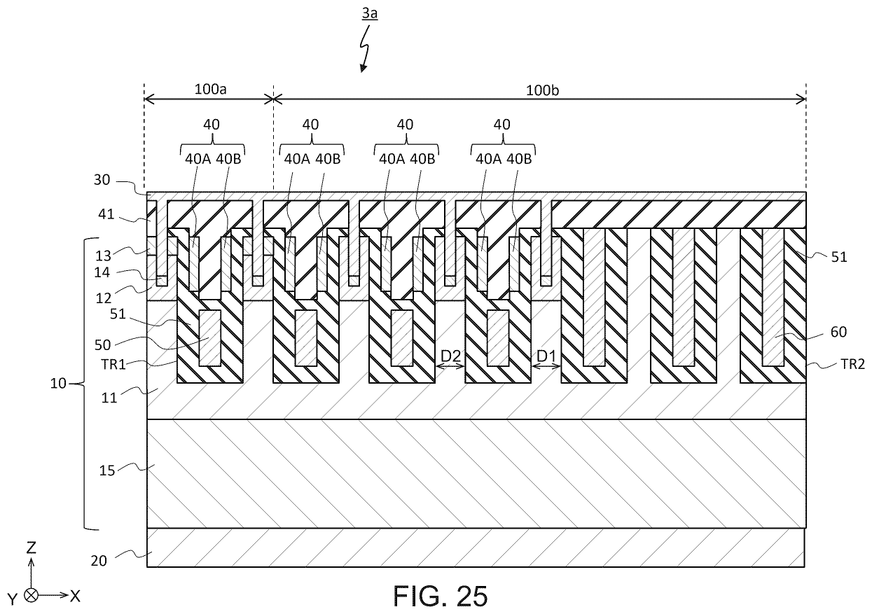

FIG. 25 is a cross-sectional view of a semiconductor device according to a third variation. In FIG. 25, differences from the semiconductor device 3 according to the third embodiment described above will be mainly described. The same components as those of the semiconductor device 3 according to the third embodiment are denoted by the same reference numerals, thereby omitting duplicate descriptions thereof.

In a semiconductor device 3a according to the present variation, a plurality of terminal trenches TR2 are lined up in the X direction. That is, the cell region 100a is surrounded by a plurality of terminal trenches TR2 in multiple layers.

Each terminal trench TR2 has a fourth electrode 60 as in the third embodiment. The impurity concentration of the fourth electrode 60 provided in each terminal trench TR2 is lower than the impurity concentration of the third electrode 50 provided in the trench TR1. Therefore, even if a plurality of terminal trenches TR2 are provided as in the present variation, the expansion stress of the fourth electrode 60 is mitigated. Therefore, in the present variation as well, it becomes possible to improve reliability.

### Fourth Embodiment

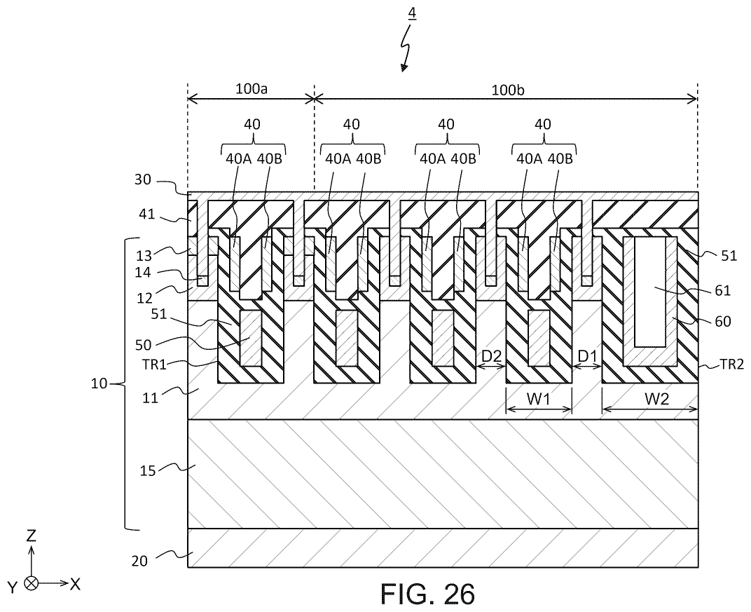

FIG. 26 is a cross-sectional view of a semiconductor device according to a fourth embodiment. In FIG. 26, the differences from the semiconductor device 1 according to the first embodiment described above will be mainly described. The same components as those of the semiconductor device 1 according to the first embodiment are denoted by the same reference numerals, thereby omitting duplicate descriptions thereof.

In a semiconductor device 4 according to present embodiment, the internal structure of the terminal trench TR2 is different from that of the first embodiment. In the semiconductor device 1 according to the first embodiment described above, a fourth electrode 60 is not provided, but a hollow portion 61 is provided in the internal space surrounded by the insulator 51.

On the other hand, in the terminal trench TR2 of the semiconductor device 4 according to the present embodiment, as shown in FIG. 26, both the fourth electrode 60 and the hollow portion 61 are provided in the internal space surrounded by the insulator 51. The fourth electrode 60 is provided along the inner surface of the insulator 51. Moreover, the fourth electrode 60 is electrically connected to the third electrode 50 of the cell region 100a. The hollow portion 61 is surrounded by the fourth electrode 60.

Further, in the semiconductor device 4 according to the present embodiment, a width W2 which corresponds to the length in the X direction of the terminal trench TR2 is larger than a width W1 which corresponds to the length in the X direction of the trench TR1. In other words, the width of a terminal insulator is larger than the width of an adjacent insulator.

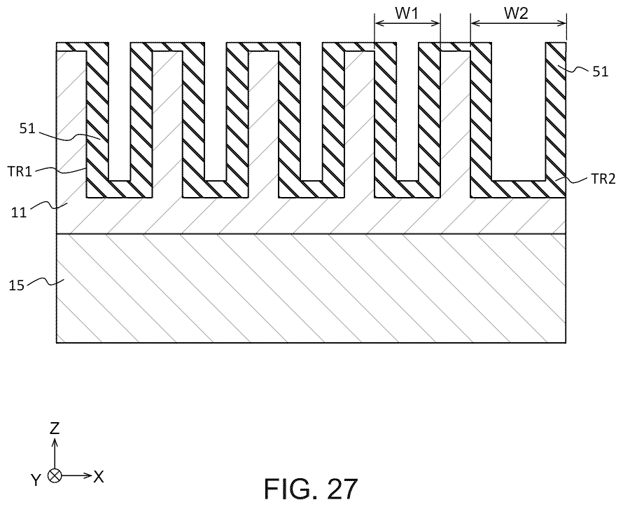

Hereafter, with reference to FIGS. 27 to 30, a manufacturing method of the semiconductor device 4 according to the present embodiment will be described. Here, different processes from those of the manufacturing method of the semiconductor device 1 according to the first embodiment described above will be mainly described.

First, as shown in FIG. 27, an insulator 51 is formed on the inner surface of each of the trench TR1 and the terminal trench TR2. At this time, the trench TR1 and the terminal trench TR2 are opened respectively such that the width W2 is larger than the width W1. That is, an opening diameter of the terminal trench TR2 is arranged to be larger than the opening diameter of the trench TR1.

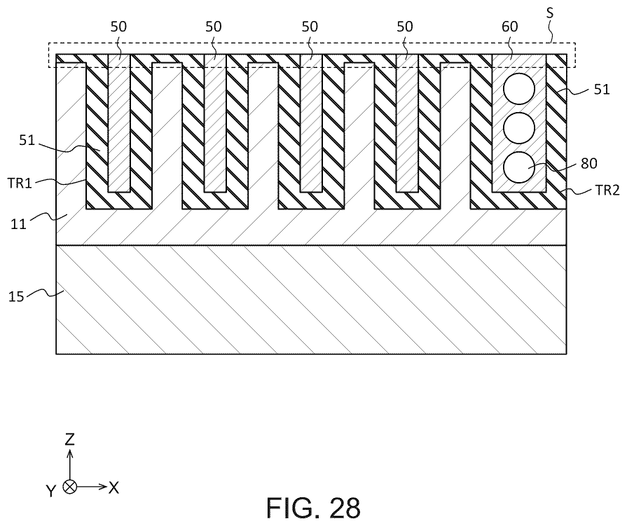

Next, as shown in FIG. 28, a third electrode 50 is formed in the trench TR1 and a fourth electrode 60 is formed in the terminal trench TR2. Subsequently, an impurity such as phosphorus (P) is implanted into the surface layer S of the third electrode 50 and the fourth electrode 60. As a result of this, the surface layer S has a high impurity concentration.

The third electrode 50 and the fourth electrode 60 can be formed, for example, by depositing polysilicon in each trench using CVD. At this time, since the width W2 is larger than the width W1, the internal capacity of the terminal trench is larger than the internal capacity of the trench TR1. As a result, a plurality of minute voids 80 are generated in the terminal trench TR2 when polysilicon is filled in the same amount as in the trench TR1.

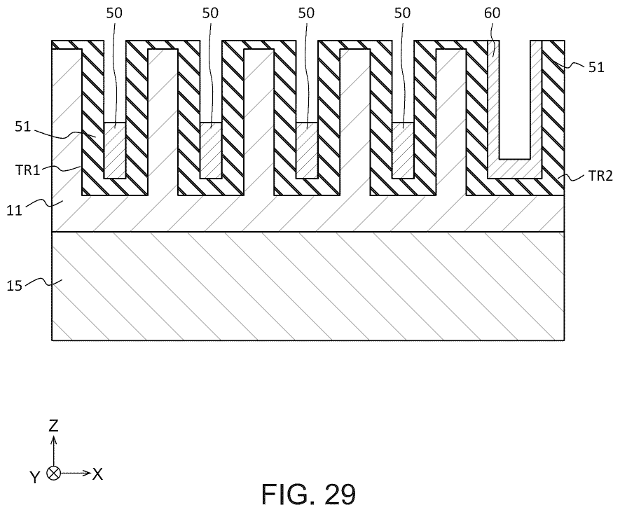

Next, as shown in FIG. 29, a part of the third electrode 50 and the fourth electrode 60 are etched by, for example, CDE. At this time, in the terminal trench TR2, voids 80 are linked together to form a slit. As a result, the fourth electrode 60 remains along the inner surface of the insulator 51.

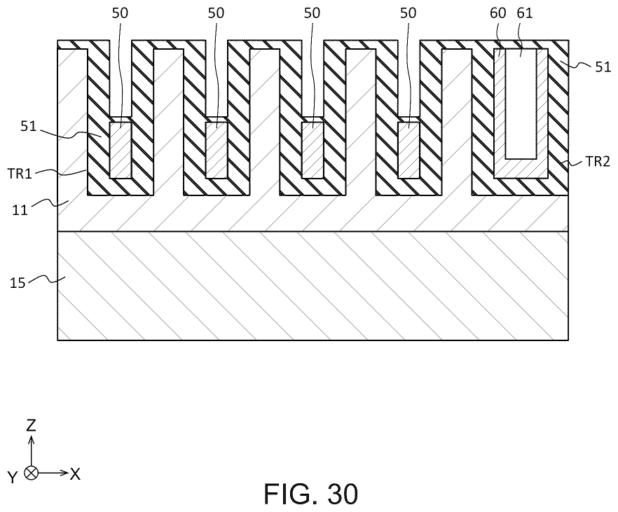

Next, as shown in FIG. 30, the upper surface of each of the third electrode 50 and the fourth electrode 60 is covered with the insulator 51, which is an oxide film, by oxidizing polysilicon contained in the third electrode 50 and the fourth electrode 60. At this time, the surface layer S of the fourth electrode 60 has a high impurity concentration as described above. Thereby, due to enhanced oxidation, the upper end opening of the terminal trench TR2 is blocked by the insulator 51. Since subsequent processes are the same as those of the first embodiment, description thereof will be omitted.

According to the present embodiment described above, while a fourth electrode 60 is formed inside the terminal trench TR2, a hollow portion 61 is also present. As a result, since the expansion stress of the fourth electrode 60 is mitigated, it becomes possible to improve reliability as in the first embodiment.

In addition, in the present embodiment, the fourth electrode 60 provided inside the terminal trench TR2 is electrically connected to the third electrode 50 in the cell region 100a. Therefore, it becomes possible to maintain a breakdown voltage in the terminal region 100b.

### (Fourth Variation)

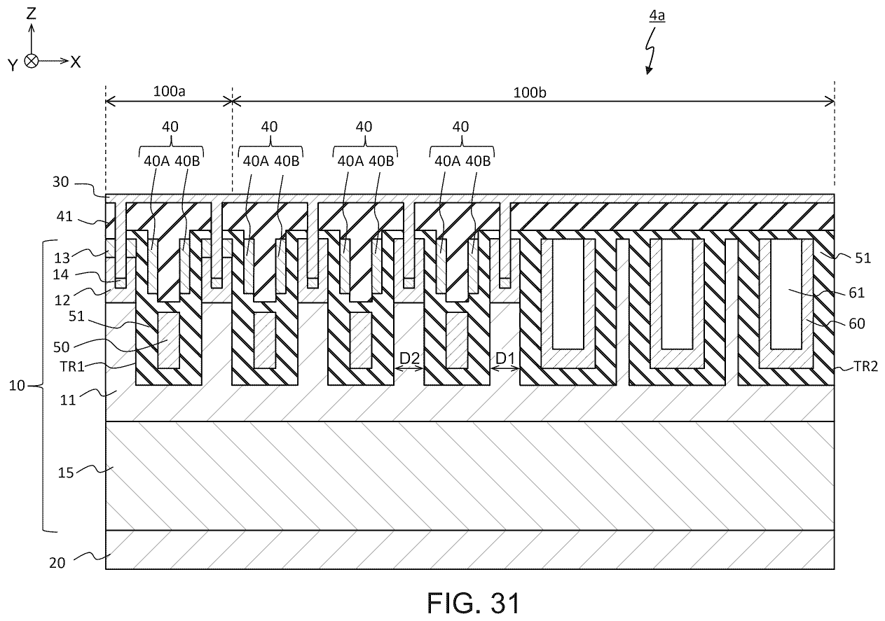

FIG. 31 is a cross-sectional view of a semiconductor device according to a fourth variation. In FIG. 31, differences from the semiconductor device 4 according to the fourth embodiment described above will be mainly described. The same components as those of the semiconductor device 4 according to the fourth embodiment are denoted by the same reference numerals, thereby omitting duplicate descriptions thereof.

In a semiconductor device 4a according to the present variation, a plurality of terminal trenches TR2 are lined up in the X direction. That is, the cell region 100a is surrounded by a plurality of terminal trenches TR2 in multiple layers.

Each terminal trench TR2 has a fourth electrode 60 and a hollow portion 61 as in the fourth embodiment. For that reason, even if a plurality of terminal trenches TR2 are provided as in the present variation, the expansion stress of the fourth electrode 60 is mitigated. Therefore, in the present variation as well, it becomes possible to improve reliability. Moreover, in the present variation as well, the fourth electrode 60 is electrically connected to the third electrode 50 of the cell region 100a. Therefore, it becomes possible to maintain a breakdown voltage in the terminal region 100b.

### Fifth Embodiment

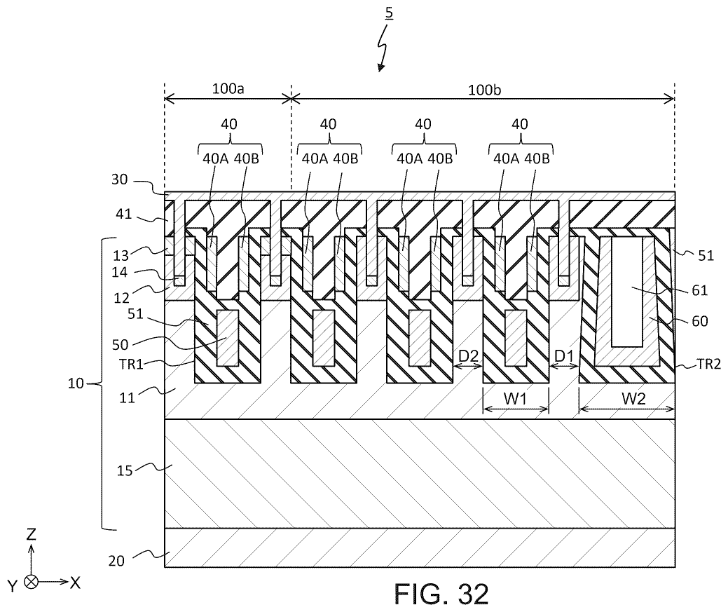

FIG. 32 is a cross-sectional view of a semiconductor device according to a fifth embodiment. In FIG. 32, differences from the semiconductor device 4 according to the fourth embodiment described above will be mainly described. The same components as those of the semiconductor device 4 according to the fourth embodiment are denoted by the same reference numerals, thereby omitting duplicate descriptions thereof.

In the semiconductor device 5 according to the first embodiment described above, the cross-sectional shape of the insulator 51 in the XZ plane is rectangular. On the other hand, in the semiconductor device 5 according to the present embodiment, the cross-sectional shape of the insulator 51 is inversely tapered as shown in FIG. 32. That is, in the insulator 51, the width of the upper end part is smaller than the width of the lower end part.

In the semiconductor device 5 configured as described above as well, as in the fourth embodiment, the fourth electrode 60 and the hollow portion 61 are provided in the terminal trench TR2. For that reason, it becomes possible to realize an improvement in reliability by stress mitigation and securement of a breakdown voltage in the terminal region 100b.

Further, the semiconductor device 5 according to the present embodiment can be manufactured by the same manufacturing process as that of the semiconductor device 4 according to the fourth embodiment. However, the terminal trench TR2 is formed in an inversely tapered shape in which the width of the upper end part is smaller than the width of the lower end part. In this case, the upper end opening width of the terminal trench TR2 becomes smaller than that in the fourth embodiment. For that reason, even if impurities are not implanted into the surface layer S to promote enhanced oxidation, it becomes easy to block the upper end opening width of the terminal trench TR2 with the insulator 51 in the process of oxidizing the fourth electrode 60.

Therefore, according to the present embodiment, since the process of implanting impurities into the surface layer S becomes unnecessary, it becomes possible to reduce the manufacturing time.

### (Fifth Variation)

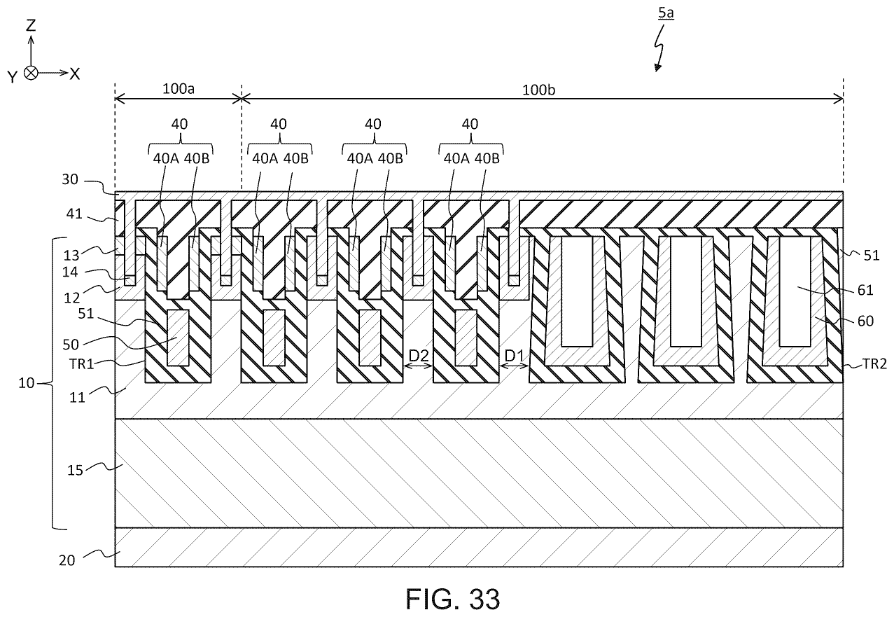

FIG. 33 is a cross-sectional view of a semiconductor device according to a fifth variation. In FIG. 33, differences from the semiconductor device 5 according to the fifth embodiment described above will be mainly described. The same components as those of the semiconductor device 5 according to the fifth embodiment are denoted by the same reference numerals, thereby omitting duplicate descriptions thereof.

In a semiconductor device 5a according to the present variation, a plurality of terminal trenches TR2 are lined up in the X direction. That is, the cell region 100a is surrounded by a plurality of terminal trenches TR2 in multiple layers.

Each terminal trench TR2 has a fourth electrode 60 and a hollow portion 61 as in the fifth embodiment. Moreover, the fourth electrode 60 is electrically connected to the third electrode 50 of the cell region 100a. As a result, in the present variation as well, expansion stress of the fourth electrode 60 is mitigated. Therefore, in the present variation as well, it becomes possible to realize an improvement in reliability by stress mitigation, and securement of a breakdown voltage in the terminal region 100b.

Moreover, in the present variation as well, the insulator 51 is formed in an inversely tapered shape. Since, as a result, it becomes easy to block the upper end opening width of the terminal trench TR2 with the insulator 51, the process of implanting impurities into the surface layer S becomes unnecessary. Therefore, it becomes possible to reduce the manufacturing time.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

1. A semiconductor device, comprising:
a semiconductor portion including a cell region and a terminal region provided outside the cell region;
a first electrode provided on a rear surface of the semiconductor portion;
a second electrode provided on a front surface side of the semiconductor portion;
a control electrode provided in the semiconductor portion via one of a plurality of first insulators arranged in a direction from the cell region to the terminal region; and
a third electrode provided in the semiconductor portion via a second insulator between itself and the control electrode, wherein
a hollow portion is provided inside a terminal insulator, which is provided closer to the terminal region side than to the control electrode, among the plurality of first insulators.

2. The semiconductor device according to claim 1, wherein an interval between an adjacent insulator, which is adjacent to the terminal insulator, among the plurality of first insulators, and the terminal insulator is less than an interval between the first insulators.

3. The semiconductor device according to claim 1, wherein a position of a lower end of the hollow portion is the same as a position of a lower end of the third electrode.

4. A semiconductor device, comprising:
a semiconductor portion including a cell region and a terminal region provided outside the cell region;
a first electrode provided on a rear surface of the semiconductor portion;
a second electrode provided on a front surface side of the semiconductor portion;
a control electrode provided in the semiconductor portion via one of a plurality of first insulators arranged in a direction from the cell region to the terminal region; and
a third electrode provided in the semiconductor portion via a second insulator between itself and the control electrode, wherein
a fourth electrode having a same thickness as that of the third electrode is provided in a terminal insulator, which is provided closer to the terminal region side than to the control electrode, among the plurality of first insulators, and the second insulator is provided on the fourth electrode.

5. The semiconductor device according to claim 4, wherein
the material of the fourth electrode is the same as the material of the third electrode.

6. The semiconductor device according to claim 4, wherein
the material of the second insulator is BPSG (boron phosphorous silicon glass).

7. The semiconductor device according to claim 1, wherein
a plurality of the terminal insulators are provided.

8. The semiconductor device according to claim 4, wherein
a plurality of the terminal insulators are provided.

9. The semiconductor device according to claim 1, wherein the semiconductor portion includes:
a first semiconductor layer provided with the trench and a terminal insulator;
a second semiconductor layer provided on the first semiconductor layer;
a third semiconductor layer provided on the second semiconductor layer;
a fourth semiconductor layer which is connected to the second electrode in the second semiconductor layer; and
a fifth semiconductor layer provided between the first semiconductor layer and the first electrode.

10. The semiconductor device according to claim 4, wherein the semiconductor portion includes:
a first semiconductor layer provided with the trench and a terminal insulator;
a second semiconductor layer provided on the first semiconductor layer;
a third semiconductor layer provided on the second semiconductor layer;
a fourth semiconductor layer which is connected to the second electrode in the second semiconductor layer; and
a fifth semiconductor layer provided between the first semiconductor layer and the first electrode.

11. The semiconductor device according to claim 9, wherein the third semiconductor layer is not present in the terminal region.

12. The semiconductor device according to claim 10, wherein the third semiconductor layer is not present in the terminal region.

13. The semiconductor device according to claim 1, wherein the third electrode is electrically connected to the second electrode.

14. The semiconductor device according to claim 4, wherein the third electrode is electrically connected to the second electrode.

15. A semiconductor device, comprising:
a semiconductor portion including a cell region and a terminal region provided outside the cell region;
a first electrode provided on a rear surface of the semiconductor portion;
a second electrode provided on a front surface side of the semiconductor portion;
a control electrode provided in the semiconductor portion via one of a plurality of first insulators arranged in a direction from the cell region to the terminal region; and
a third electrode provided in the semiconductor portion via a second insulator between itself and the control electrode, wherein
a fourth electrode is provided in a terminal insulator, which is provided closer to the terminal region side than to the control electrode, among the plurality of first insulators, and
a concentration of impurities contained in the fourth electrode is lower than a concentration of the impurities contained in the third electrode.

16. The semiconductor device according to claim 15, wherein
the material of the fourth electrode is a non-doped polysilicon.

17. The semiconductor device according to claim 1, further comprising a fourth electrode surrounding the hollow portion inside the terminal insulator.

18. The semiconductor device according to claim 17, wherein the width of the terminal insulator is larger than the width of an adjacent insulator which is adjacent to the terminal insulator, among the plurality of first insulators.

19. The semiconductor device according to claim 17, wherein the fourth electrode is electrically connected to the third electrode in the cell region.

20. The semiconductor device according to claim 17, wherein the terminal insulator has an inversely tapered cross-sectional shape.
